(19) United States
(12) Patent Application Publication
(10) Pub. No.: US 2010/0011785 A1
(43) Pub. Date: Jan. 21, 2010

(54) TUBE DIFFUSER FOR LOAD LOCK CHAMBER

(75) Inventors: Mehran Behdjat, San Jose, CA (US); Shinichi Kurita, San Jose, CA (US); Makoto Inagawa, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., SANTA CLARA, CA (US)

(21) Appl. No.: 12/501,799

(22) Filed: Jul. 13, 2009

Related U.S. Application Data
(60) Provisional application No. 61/080,929, filed on Jul. 15, 2008.

(51) Int. Cl. C23C 16/00

(52) U.S. Cl. 62/62; 118/723 R

(57) ABSTRACT

Embodiments disclosed herein generally provide a load lock chamber capable of controlling the temperature of the substrate therein. The load lock chamber may have one or more cooling fluid introduction passages that extend across the chamber. Cooling fluid, such as nitrogen gas, may flow through the cooling fluid passage and enter the load lock chamber. The cooling fluid passages may have openings to permit the cooling fluid to exit the passages and enter the load lock chamber. The openings may be arranged to permit a greater amount of cooling fluid to enter the load lock at locations corresponding to the substrate positions that are in contact with an end effector that places the substrate into the load lock chamber. Additionally, the openings may be arranged to permit a greater amount if cooling fluid to enter the load lock chamber in the center of the chamber as compared to the edge of the chamber.

### CROSS-REFERENCE TO RELATED APPLICATIONS

This application claims benefit of U.S. Provisional Patent Application Ser. No. 61/080,929, filed Jul. 15, 2008, which is herein incorporated by reference.

### BACKGROUND OF THE INVENTION

1. Field of the Invention

Embodiments disclosed herein relate to a tube diffuser for a load lock chamber.

2. Description of the Related Art

During substrate processing, substrates may be heated by an annealing process or by the processing environment. For example, in a plasma enhanced chemical vapor deposition (PECVD) process, the plasma may heat the substrate to temperatures greater than 200 degrees Celsius. In some cases, multiple processes may be performed on the substrate. These multiple processes may be performed in separate chambers. A plurality of processing chambers may be coupled together around a transfer chamber to permit quick transfer between processing chambers without exposing the substrate to an ambient environment which could contaminate the substrate. The substrate may be introduced to the multiple processing chamber system from a factory interface through a load lock chamber. The substrate may also be removed from the system through the load lock chamber. When transferring the substrate back to the factory interface, it may be beneficial to reduce the temperature of the substrate prior to placing the substrate in the factory interface.

Therefore, there is a need in the art for a load lock chamber capable of cooling a substrate placed therein.

### SUMMARY OF THE INVENTION

Embodiments disclosed herein generally provide a load lock chamber capable of controlling the temperature of the substrate therein. The load lock chamber may have one or more cooling fluid introduction passages that extend across the chamber. Cooling fluid, such as nitrogen gas, may flow through the cooling fluid passage and enter the load lock chamber. The cooling fluid passages may have openings to permit the cooling fluid to exit the passages and enter the load lock chamber. The openings may be arranged to permit a greater amount of cooling fluid to enter the load lock chamber at locations corresponding to the substrate positions that are in contact with an end effector that places the substrate into the load lock chamber. Additionally, the openings may be arranged to permit a greater amount of cooling fluid to enter the load lock chamber in the center of the chamber as compared to the edge of the chamber.

In one embodiment, a substrate cooling method is provided. Such cooling method includes introducing a cooling fluid into the load lock chamber. The cooling fluid introduction permits a greater amount of cooling fluid to enter the load lock chamber at a location corresponding to a center of the substrate as compared to the edge of the substrate and a greater amount of cooling fluid to enter the load lock chamber at the one or more locations where the substrate contacts the end effector robot during insertion as compared to other areas of the substrate.

In another embodiment, a cooling fluid introduction tube is provided. The cooling fluid introduction tube includes a plurality of openings through an outer surface of the tube. The openings are radially distributed along the portion of the tube and in a pattern that is unevenly distributed longitudinally along the tube.

In another embodiment, an apparatus for substrate processing is provided. The apparatus includes a factory interface, a transfer chamber, and a load lock chamber. The load lock chamber includes one or more temperature control elements that extend across the load lock chamber. Each temperature control element has a plurality of openings therethrough that permit a temperature control fluid to enter the load lock chamber in a greater volume in a first area of the load lock chamber as compared to a second area of the load lock chamber. The temperature of first area of the load lock chamber is higher than that of the second area of the load lock chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top view illustrating a substrate processing system;

FIG. 2 is a schematic drawing of an existing load lock chamber for wafer cooling;

FIG. 3A is a schematic drawing showing a cooling fluid introducing element according to one embodiment;

FIG. 3B is a schematic drawing showing a cooling fluid introducing element according to another embodiment;

FIG. 4 is a bottom view of a load lock chamber according to one embodiment; and

FIG. 5 is another bottom view of a load lock chamber according to another embodiment.

### DETAILED DESCRIPTION

Embodiments disclosed herein generally provide a load lock chamber capable of controlling the temperature of the substrate therein. The load lock chamber may have one or more cooling fluid introduction passages that extend across the chamber. Cooling fluid, such as nitrogen gas, may flow through the cooling fluid passage and enter the load lock chamber. The cooling fluid passages may have openings to permit the cooling fluid to exit the passages and enter the load lock chamber. The openings may be arranged to permit a greater amount of cooling fluid to enter the load lock chamber at locations corresponding to the substrate positions that are in contact with an end effector that places the substrate into the load lock chamber. Additionally, the openings may be arranged to permit a greater amount of cooling fluid to enter the load lock chamber in the center of the chamber as compared to the edge of the chamber.

The embodiments described below may be practiced in a load lock chamber available from AKT America, Inc., a subsidiary of Applied Materials, Inc, Santa Clara, Calif. It is to be understood that the embodiments may be practiced in other chambers, including those sold by other manufacturers.

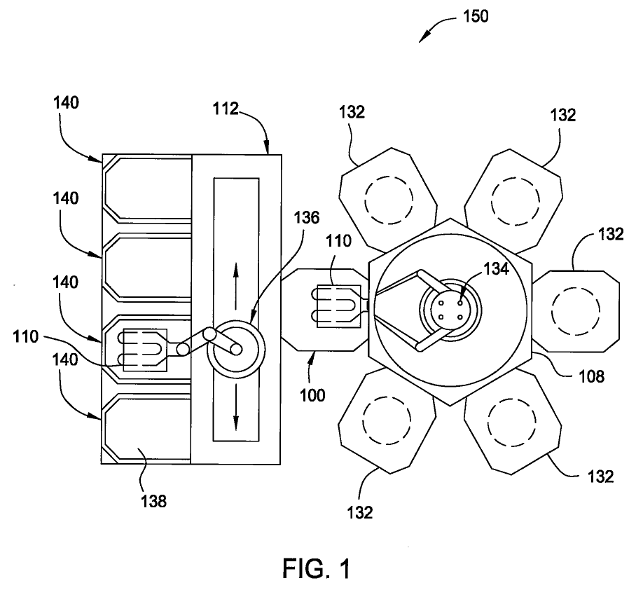

A substrate processing system is shown in FIG. 1. The substrate processing system 150 includes a transfer chamber 108 coupled to a factory interface 112 by a load lock chamber 100 having a plurality of substrate chambers (not shown). Those substrate chambers may be vertically stacked and environmentally isolated. The configuration of vertically stacked substrate chambers contributes to reduced size. Moreover, more than one substrate 110 could be simultaneously present in the load lock chamber 100, increasing the throughput of the substrate processing system 150. The transfer chamber 108 may have at least one dual blade vacuum robot 134 disposed therein that is adapted to transfer substrates 110 between a plurality of circumscribing process chambers 132 and the load lock chamber 100. In one embodiment, one of the process chambers 132 is a pre-heat chamber that thermally conditions substrates 110 prior to processing. The transfer chamber 108 may be maintained at a vacuum condition to eliminate the necessity of adjusting the pressure between the transfer chamber 108 and the individual process chambers 132 after the transfer of each substrate 110.

The factory interface 112 may include a plurality of substrate storage cassettes 138 and a dual blade atmospheric robot 136. The cassettes 138 may be disposed in a plurality of bays 140 formed on one side of the factory interface 112 in a removable manner. The atmospheric robot 136 is adapted to transfer substrates 110 between the cassettes 138 and the load lock chamber 100. The load lock chamber 100 is an enclosed structure and the pressure therein may be adjusted.

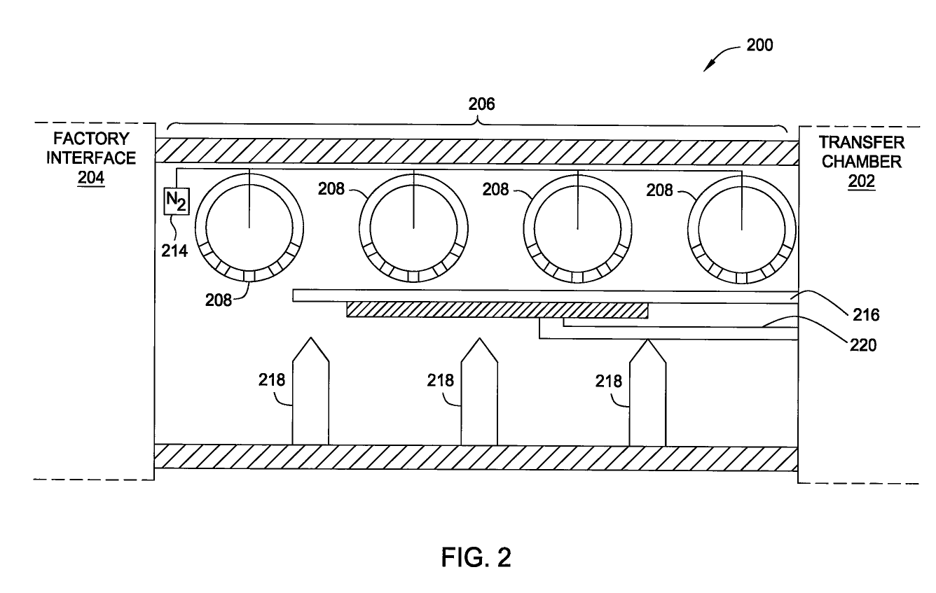

FIG. 2 is a schematic diagram showing a load lock chamber 200 according to one embodiment of the present invention. The load lock chamber 200 may be disposed between a transfer chamber 202 and a factory interface 204. The load lock chamber 200 may receive substrates from the transfer chamber 202 to be sent to the factory interface 204. Additionally, the load lock chamber 200 may receive substrates from the factory interface 204 to be processed in processing chambers coupled to the transfer chamber 202. The load lock chamber 200 may include an enclosure 206 in which more than one cooling fluid introduction element 208 is disposed. In one embodiment of the present invention, the cooling fluid introduction element 208 is a cooling pipe connected to a cooling source 214 that introduces a cooling fluid to the cooling pipe 208. In one embodiment of the present invention, the cooling fluid comprises nitrogen gas. The cooling source 214 is configured to supply the nitrogen gas to all of the cooling pipes 208 to permit the cooling pipes 208 to facilitate the cooling of the substrate 216. The load lock chamber 200 further includes a plurality of substrate supporting elements 218. In one embodiment, the substrate support element 218 is a lift pin. The lift pins 218 may be disposed between the cooling pipes 208. Initially, the substrate 216 is inserted into the load lock chamber 200 by an end effector robot 220. The end effector robot 220 then lowers the substrate 216 onto the lift pins 218. Another end effector robot of the factory interface 204 (not shown) could be configured to raise the substrate 220 from the lift pins 218 before moving the substrate 216 to the factory interface. While the cooling pipes 208 have been shown to be positioned above the substrate 216, it is to be understood that the cooling pipes 208 may be positioned below the substrate 216 in the load lock chamber 200.

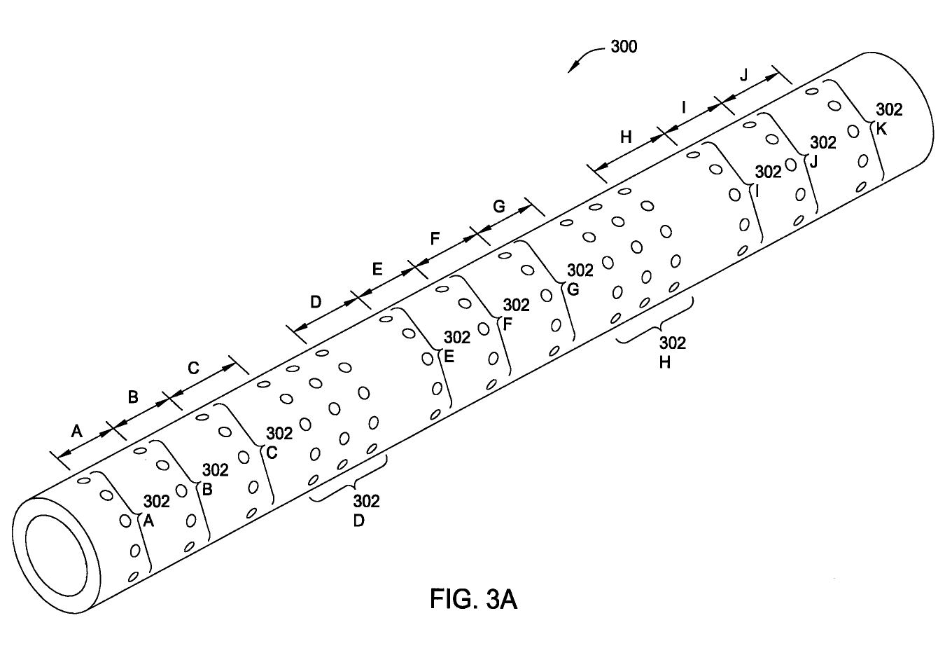

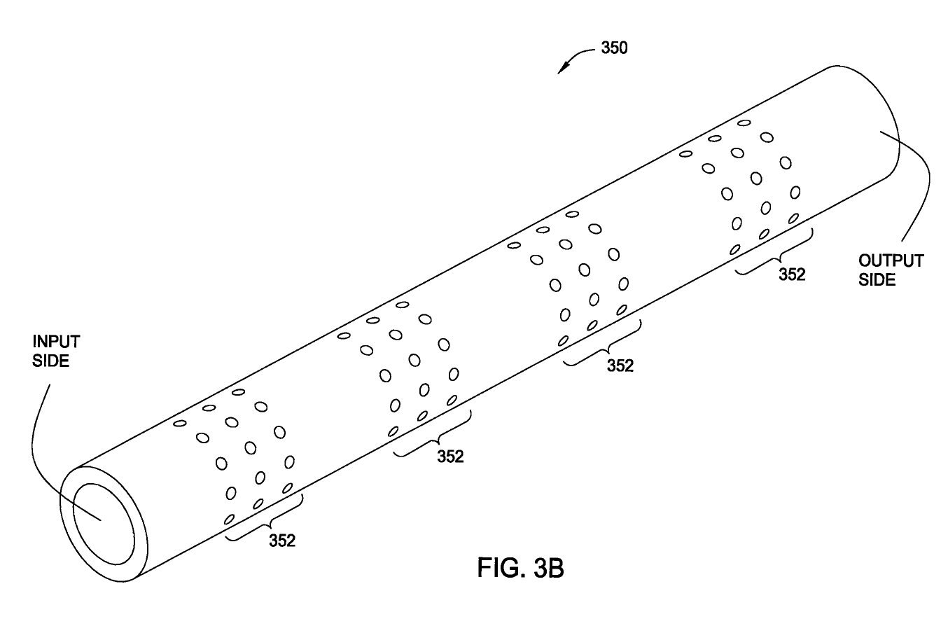

FIG. 3A is a schematic drawing showing a cooling pipe 300 according to one embodiment of the present invention. The cooling pipe 300 comprises a plurality of openings 302 on the periphery thereof. As such, the cooling fluid may exit the cooling pipe 300 through the openings 302 to help reduce the temperature of the substrate. In one implementation, those openings 302 may be grouped (e.g., 302A) at desired cooling locations. The center of the substrate may be at a higher temperature than the edge of the substrate, therefore more openings 302 may be at the central locations of the cooling pipe 300 corresponding to areas of the substrate associated with higher temperatures.

Therefore, the distance A between opening groups 302A and 302B may be larger than the distance B between another two groups of the openings 302B and 302C. The distance C between the opening groups 302C and 302D may be even shorter than the distance B while the distance D between another two groups of openings 302D and 302E may be shorter than the distance C. The distance E between opening groups 302E and 302F could be the shortest one as these two groups of openings 302 are at the positions corresponding to the center of the substrate. The distance J between openings 302K and 302J may be larger than the distance I between the openings 302J and 302I, which may be larger than the distance H separating openings 302I and 302H. At the same time, the distance H between openings 302H and 302G may be configured to be larger than the distance G between the openings 302H and 302G. The distance F, which may be shorter than the distance G, is the distance between openings 302G and 302F. Under this arrangement, the areas of the substrate of higher temperatures correspond to more concentrated groups of openings 302. Thus, more cooling fluid could flow into those areas to reduce the higher temperatures.

The locations of where the opening groups 302D and 302H are placed correspond to the locations of an end effector carrying the substrate. As those end effectors are in direct contact with the substrate, the temperature of the substrate at the locations that contact the end effectors may be higher than other portions of the substrate. To reduce the temperature of the substrate, the number of the openings in the opening groups 302D and 302H could be configured to be larger than that of other groups of openings. Therefore, more cooling fluid could flow into the locations of the substrate that were contacted by the end effector to help reduce the temperature.

FIG. 3B is another schematic drawing showing a cooling pipe 350 according to one embodiment of the present invention. Unlike the cooling pipe 300 where openings 302 are un-evenly distributed, openings 352 of the cooling pipe 350 are uniformly placed on the outer surface of the cooling pipe 350. As the temperature distribution pattern of the substrate remains the same (in other words, the center and the areas adjacent to the center of the substrate are of higher temperatures), the diameter of the openings 352 at the positions corresponding to those higher temperature areas of the substrate is configured to be larger than that of other openings 352 located at positions corresponding to the lower temperature areas of the substrate. Moreover, the openings 352 whose locations correspond to the end effector in direct contact with the substrate may be larger in diameter when compared with that of other openings located somewhere else. With openings larger in diameter, more cooling fluid may flow to the higher temperature areas to help reduce the higher temperatures.

The cooling pipe 350 may have an inner pipe and a surrounding outer pipe. The diameters of the openings of the inner pipe may increase from the input side where the cooling fluid enters into the cooling pipe 350. By increasing the diameter, the flow restriction of the cooling fluid is reduced the further away from the source. Thus, the cooling fluid may flow through the entire length of the pipe rather than disproportionately flowing out of the openings closest to the cooling fluid source. Because the cooling fluid extends through the entire inner pipe, the cooling fluid will be distributed across the entire plenum between the inner pipe and the surrounding outer pipe. The cooling fluid may then be evenly distributed through the outer pipe by utilizing openings in the outer pipe that have the same diameter. Therefore, the flow of cooling fluid through the openings of the outer pipe may be substantially equal for all openings and the location of the openings may be preselected to suit the needs of the user.

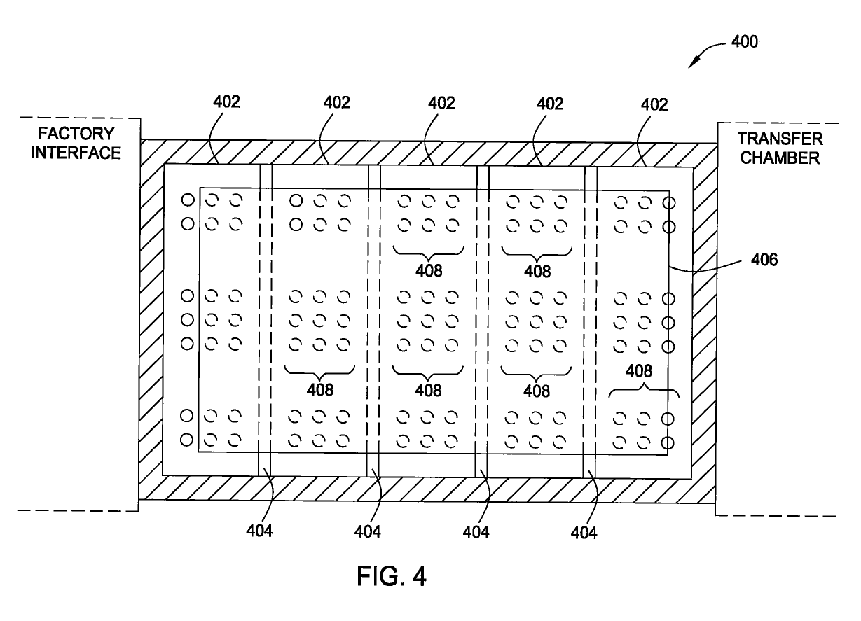

FIG. 4 is a bottom view of a load lock chamber 400 according to one embodiment of the present invention. The load lock chamber 400 includes a plurality of cooling pipes 402. The cooling pipes 402 are separated from each other by small gaps 404. Those small gaps 404 are where the substrate lift elements (lift pins) may be placed. The lift pins are configured to support a substrate 406 when the latter is inside the load lock chamber 400. Openings 408 are placed on the periphery of the cooling pipes 402. Since the center of the substrate 406 and the areas adjacent to the center are of higher temperatures when the substrate 406 is inside the load lock chamber 400, more openings 408 may be present at the positions corresponding to the areas of higher temperatures. Therefore, more cooling fluid could be directed to those areas and the temperatures thereof could be lowered accordingly.

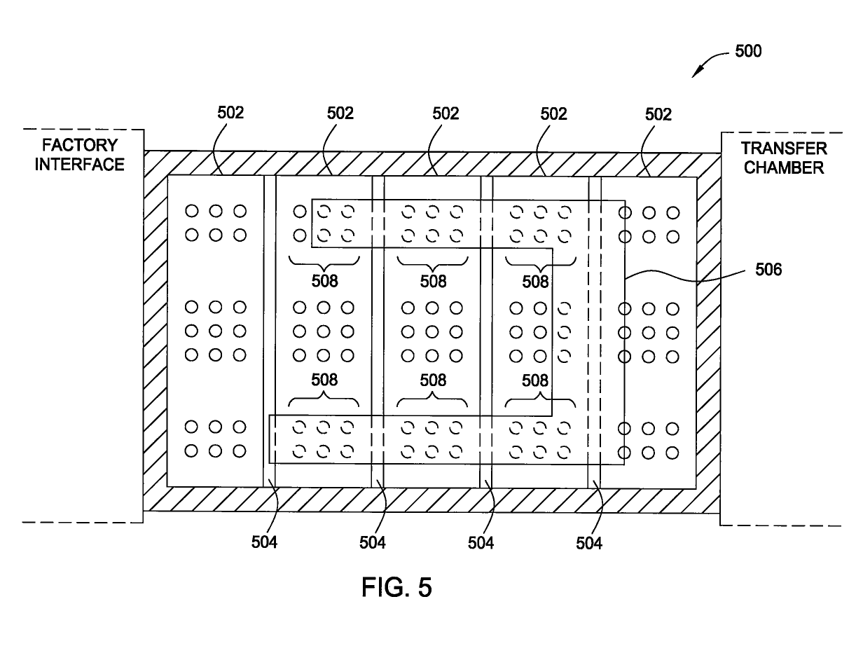

FIG. 5 is another bottom view showing a load lock chamber 500 according to one embodiment of the present invention. The load lock chamber 500 includes a plurality of cooling pipes 502 separated by small gaps 504. For the purpose of illustration, FIG. 5 only shows end effectors 506 without any substrate placed thereon. Each of the cooling pipes 502 includes a plurality of openings 508 on the periphery thereof. The cooling fluid emits from those openings 508 to lower the temperature of the end effectors 506. The end effectors 506 are adapted to carry the substrate (not shown) either from the transfer chamber or the factory interface. The portions of the substrate that are in contact with the end effectors 506 when the end effectors 506 move the substrate may have higher temperatures than other portions of the substrate. Therefore, more of the openings 508 from are placed at the locations corresponding to the parts of the end effectors 506 that are in contact with the substrate.

Because the temperatures of the center of the substrate and the areas adjacent to the center of the substrate may be of higher temperatures than other portions of the substrate, more cooling fluid may be delivered to the high temperature areas. Additionally, because the areas of the substrate in contact with the end effectors may be at higher temperatures when compared with the other areas of the substrate, more cooling fluid may be delivered to the high temperature areas. Thus, a more uniform substrate cooling could be performed.

The load lock chamber according to the present invention is capable of controlling the temperature of the substrate by causing more cooling fluid to flow to higher temperature areas of the substrate. To serve that purpose, the cooling fluid introduction element of the load lock chamber may be designed to compensate for the temperature distribution of the substrate by placing more openings at the positions corresponding to the higher temperature areas of the substrate.

While the foregoing is directed to embodiments of the present invention, other and further embodiments of the invention thus may be devised without departing from the basic scope thereof, and the scope thereof is determined by the claims that follow.

1. A load lock chamber for transferring a substrate, comprising:
a load lock chamber body having at least two first openings to permit insertion and removal of the substrate from the body;
one or more substrate support elements disposed in the chamber body; and
one or more cooling fluid introduction elements extending across the chamber body and having a plurality of non-uniformly distributed openings to permit a cooling fluid to exit the one or more cooling fluid introduction elements and enter the load lock chamber body.

2. The load lock chamber of claim 1, wherein the one or more cooling fluid introduction elements have a greater number of second openings located in an area that correspond to the areas of the substrate that contact an end effector when the end effector moves the substrate.

3. The load lock chamber of claim 1, wherein the one or more cooling fluid introduction elements have a greater number of second openings located in an area that corresponds to the center of the substrate as compared to the edge of the substrate.

4. The load lock chamber of claim 3, wherein the diameter of the second openings is greater in an area corresponding to the center of the substrate as compared to the edge of the substrate.

5. The load lock chamber of claim 3, the one or more cooling fluid introduction elements have a greater number of second openings located in an area corresponding to a location where an end effector that inserts the substrate into the load lock chamber contacts the substrate during insertion.

6. The load lock chamber of claim 5, wherein a diameter of the second openings is larger in an area corresponding to a location where the end effector that inserts the substrate into the load lock chamber contacts the substrate during insertion as compared to other areas.

7. The load lock chamber of claim 1, wherein the one or more cooling fluid introduction elements are below the substrate.

8. The load lock chamber of claim 1, the one or more cooling fluid introduction elements further comprise a plurality of cooling fluid introduction elements, and the load lock chamber further comprises one or more lift pins disposed between adjacent cooling fluid introduction elements.

9. The load lock chamber of claim 1, wherein the one or more cooling fluid introduction elements are disposed in a plane generally parallel to a plane where the substrate is supported.

10. The load lock chamber of claim 1, wherein the one or more cooling fluid introduction elements extend substantially perpendicular to a direction in which the substrate is inserted.

11. A method for cooling a substrate, comprising:
inserting the substrate into a load lock chamber, the substrate inserted by an end effector robot that contacts the substrate at one or more locations;
introducing a cooling fluid into the load lock chamber, the introducing including one or more conditions selected from the group consisting of:
permitting a greater amount of cooling fluid to enter the load lock chamber at a location corresponding to a center of the substrate as compared to the edge of the substrate; and
permitting a greater amount of cooling fluid to enter the load lock chamber at the one or more locations where the substrate contacts the end effector robot during insertion as compared to other areas of the substrate.

12. The method of claim 11, wherein the cooling fluid is introduced from below the substrate.

13. The method of claim 11, wherein the cooling fluid is a nitrogen gas.

14. An apparatus, comprising:
a transfer chamber; and
a load lock chamber, the load lock chamber having one or more temperature control elements that extend across the load lock chamber and have a plurality of openings therethrough that permit a temperature control fluid to enter the load lock chamber in a greater volume in a first area of the load lock chamber as compared to a second area of the load lock chamber.

15. The apparatus of claim 14, wherein the load lock chamber is a triple single slot load lock chamber (TSSL).

16. The apparatus of claim 14, the one or more temperature control elements have a greater number of openings located in the first area that corresponds to areas of a substrate that contact an end effector when the end effector moves the substrate.

17. The apparatus of claim 14, the one or more temperature control elements have a greater number of openings located in the first area of corresponds to the center of a substrate as compared to the edge of the substrate.

18. The apparatus of claim 17, wherein the diameter of the openings is greater in the first area corresponding to the center of the substrate as compared to the edge of the substrate.

19. The apparatus of claim 18, the one or more temperature control elements have a greater number of openings located in the first area corresponding to a location where an end effector that inserts the substrate into the load lock chamber contacts the substrate during insertion.

20. The apparatus of claim 14, wherein the one or more cooling fluid introduction elements extend substantially perpendicular to a direction in which a substrate is inserted.
